(19) United States
(12) Patent Application Publication
(10) Pub. No.: US 2026/0119945 A1
(43) Pub. Date: Apr. 30, 2026

(54) ADVANCED QUANTUM PROCESSING SYTEMS

(71) Applicant: Silicon Quantum Computing Pty Limited, Kensington (AU)

(72) Inventors: Michelle Yvonne Simmons, Kensington (AU); Samuel Keith Gorman, Kensington (AU); Ludwik Kranz, Kensington (AU); Samuel Sutherland, Kensington (AU); Casey Myers, Kensington (AU); Ian Thorvaldson, Kensington (AU)

(21) Appl. No.: 19/118,763

(22) PCT Filed: Oct. 6, 2023
(86) PCT No.: PCT/AU2023/050978

§ 371 Date: Apr. 5, 2025

(30) Foreign Application Priority Data
Oct. 6, 2022 (AU) 2022902912

(51) Int. Cl. G06N 10/40; H10D 48/00

(52) U.S. Cl. CPC G06N 10/40; H10D 48/3835

(57) ABSTRACT

There is provided a method for performing one or more quantum operations on a quantum processor. Wherein the quantum processor comprises a plurality of quantum dots in a semiconductor substrate and at least a subset of the quantum dots being multi-dopant quantum dots. Further each multi-dopant quantum dot comprises two or more dopant atoms and at least one of the plurality of quantum dots confining an unpaired electron/hole. The method comprises performing the one or more quantum operations on the quantum processor using one or more operation modes including: using the spin of the unpaired electron/hole of a quantum dot as a data qubit; using a multi-dopant quantum dot as an error corrected logical qubit; using at least one nuclear spin of a dopant atom of a multi-dopant quantum dot as a data qubit; or using the spin of the unpaired electron/hole and at least one nuclear spin of a dopant atom of a multi-dopant quantum dot as data qubits.

### TECHNICAL FIELD

Aspects of the present disclosure are related to advanced processing systems and methods for operating the same, and more particularly, to quantum processing systems which are controllable to perform quantum operations.

### BACKGROUND

The developments described in this section are known to the inventors. However, unless otherwise indicated, it should not be assumed that any of the developments described in this section qualify as prior art merely by virtue of their inclusion in this section, or that those developments are known to a person of ordinary skill in the art.

Large-scale quantum processing systems hold the promise of a technological revolution, with the prospect of solving problems that are out of reach with classical machines. To date, a number of different structures, materials, and architectures have been proposed to implement quantum processing systems and fabricate their basic information units (quantum bits or qubits).

One way of fabricating qubits, for example, is to use the nuclear or the electron spin of phosphorus donor atoms in silicon such that the nuclear/electron spin of each phosphorus donor atom acts as a qubit. This fabrication technique offers near perfect qubit state encoding due to the addressability and long coherence of the phosphorus spins. Further, qubits fabricated in this manner have demonstrated second-long lifetimes and benefit from a semiconducting host enabling electrical addressing and high fidelities.

To start seeing the computational advantage that quantum processing systems can offer, however, basic quantum operations need to be performed on such quantum processing systems-which is not easy.

### SUMMARY

According to a first aspect of the present disclosure, there is provided a method for performing one or more quantum operations on a quantum processor, the quantum processor comprising a plurality of quantum dots in a semiconductor substrate, at least a subset of the quantum dots being multi-dopant quantum dots, each multi-dopant quantum dot comprising two or more dopant atoms, and at least one of the plurality of quantum dots confining an unpaired electron/hole, the method comprising: performing the one or more quantum operations on the quantum processor using one or more operation modes including: using the spin of the unpaired electron/hole of a quantum dot as a data qubit; using a multi-dopant quantum dot as an error corrected logical qubit; using at least one nuclear spin of a dopant atom of a multi-dopant quantum dot as a data qubit; or using the spin of the unpaired electron/hole and at least one nuclear spin of a dopant atom of a multi-dopant quantum dot as data qubits.

The adjacent quantum dots in the plurality of quantum dots may be positioned approximately 5-20 nanometers apart.

In some embodiments, when the spin of the unpaired electron/hole of a quantum dot is used as a data qubit, the nuclear spins of the one or more dopant atoms in the quantum dot are used as atomic magnets.

Further, when the multi-dopant quantum dot is used as the error corrected logical qubit, the spin of the unpaired electron/hole of the multi-dopant quantum dot is used as a data qubit and the one or more nuclear spins of the multi-dopant quantum dot are used for error-correction. Similarly, when at least one nuclear spin of a dopant atom is used as a data qubit, and the corresponding spin of the unpaired electron/hole is used for readout, addressability, or coupling of data qubits with adjacent quantum dots.

In some examples, coupling with adjacent quantum dots is performed via electron/hole spin shuttling between the multi-dopant quantum dot and an adjacent quantum dot or exchange coupling between an unpaired electron/hole of the multi-dopant quantum dot and an unpaired electron/hole of the adjacent multi-dopant quantum dot.

In some examples, the nuclear spins of the dopant atoms are controlled using nuclear magnetic resonance or EDSR. In some examples the spin of the unpaired electron/hole is controlled using electrical spin resonance or EDSR.

In some embodiments, the one or more quantum operations includes at least one of single-qubit operations, two-qubit operations, or multi-qubit operations.

In some embodiments, when the one or more quantum operations is a multi-qubit operation, the quantum operation is performed using the spin of the unpaired electron/hole and the nuclear spins of the dopant atoms in a multi-dopant quantum dot.

According to a second aspect of the present disclosure, there is provided a method for performing one or more quantum operations on a quantum processor, the quantum processor comprising a plurality of quantum dots in a silicon substrate, at least a subset of the quantum dots being multi-dopant quantum dots each comprising two or more dopant atoms, and at least one of the plurality of quantum dots confining an unpaired electron/hole, the method comprising: performing the one or more quantum operations on the quantum processor using one or more modes of operation comprising at least one of: using one or more of the multi-dopant quantum dots as error corrected logical qubits; using at least one nuclear spin of a dopant atom of a multi-dopant quantum dot as a data qubit; or using the spin of the unpaired electron/hole and at least one nuclear spin of a multi-dopant quantum dot as a data qubit.

According to a third aspect of the present disclosure, there is provided a quantum processor comprising: a silicon substrate, a layer of dielectric material on the silicon substrate; a plurality of quantum dots fabricated in the silicon substrate, each quantum dot comprising at least one dopant atom, at least a subset of the quantum dots being multi-dopant quantum dots, and one or more of the quantum dots confining an unpaired electron/hole; wherein during operation of the quantum processor the spin of the unpaired electron/hole and/or the nuclear spin of the one or more dopant atoms in a quantum dot are used as data qubits.

The number of dopant atoms and/or spatial configuration of the dopant atoms within each quantum dot is selected to achieve a predefined hyperfine coupling range between the spin of the electron/hole and each of the nuclear spins within each quantum dot. Further, the distance between two adjacent quantum dots is selected to achieve a predefined tunnel coupling range between the spins of the electron/hole bound to the adjacent dots. In some examples, the distance between adjacent quantum dots is approximately 5-20 nanometers. Further, in some examples, the predefined tunnel coupling is in a range of 1 kHz
1 THz

The size of each quantum dot in the quantum processor may be less than 3 nanometers. Further, the plurality of quantum dots can be arranged in a one-dimensional, two-dimensional, or three-dimensional geometric pattern.

In some embodiments, the quantum processor further includes one or more sensors for measuring the final state of a qubit associated with a quantum dot of the plurality of quantum dots. In some embodiments, the quantum processor further includes one or more reservoirs near the quantum dots. The one or more reservoirs provide electrons/holes for confinement in one or more of the quantum dots and the distance between the one or more reservoirs and the one or more quantum dots is approximately between 10-25 nanometers.

During operation of the quantum processor of the third aspect, when the spin of an unpaired electron/hole of a quantum dot is used as a data qubit, the nuclear spins of the one or more dopant atoms of the quantum dot are used for error correction or as atomic magnets; when the nuclear spins of the one or more dopant atoms are used as data qubits, the spin of the unpaired electron/hole is used for addressing or measuring the spins of the one or more dopant atoms; or when the nuclear spins of the one or more dopant atoms are used as data qubits, the spin of the unpaired electron/hole is used for coupling the quantum dot to an adjacent quantum dot.

According to a fourth aspect of the present disclosure there is provided a method for performing a multi-qubit operation. The method includes providing a multi-dopant quantum dot comprising two or more dopant atoms and an unpaired electron/hole confined in the quantum dot and using a spin of the unpaired electron/hole and the nuclear spins of the two or more dopant atoms as qubits and performing the multi-qubit operation using the qubits.

### BRIEF DESCRIPTION OF DRAWINGS

While the invention is amenable to various modifications and alternative forms, specific embodiments are shown by way of example in the drawings and are described in detail. It should be understood, however, that the drawings and detailed description are not intended to limit the invention to the particular form disclosed. The intention is to cover all modifications, equivalents, and alternatives falling within the spirit and scope of the present invention as defined by the appended claims.

FIG. 1 is a schematic illustrating a conventional architecture based on single donor qubits where qubits are controlled with alternating A-gates and J-gates.

FIG. 2 shows a conventional quantum processor architecture that includes three planes.

FIG. 3 illustrates an example flopping mode qubit called a flip-flop qubit FIG. 4 shows another flopping mode qubit architecture.

FIG. 5 shows an example multi-donor quantum dot according to aspects of the present disclosure.

FIG. 6 shows a schematic of three different multi-donor quantum dots.

FIG. 7 shows an example of 1D architecture with five multi-donor quantum dots.

FIG. 8 shows other examples of 1D chains with varying inter-dot distances and angles.

FIG. 9 shows three examples of 2D architectures comprising multi-donor quantum dots.

FIG. 10 shows four examples of 3D crystal structures of multi-donor quantum dots.

FIG. 11A illustrates an example quantum processor according to aspects of the present disclosure.

FIG. 11B illustrates an example method for fabricating the quantum processor of FIG. 11A

FIG. 12A shows an example 3P quantum dot.

FIG. 12B shows an example algorithm using a subset of the control methods for use within a 3P dot.

FIGS. 13A and 13B show the eight ESR transitions and frequencies for a 3P quantum dot, respectively, and FIG. 13C illustrates the electron-nuclear couplings for this 3P quantum dot.

FIG. 14 shows a schematic protocol for measuring a single nuclear spin within a 3P quantum dot.

FIG. 15 shows a schematic protocol for measuring all nuclear spins within a 3P quantum dot.

FIG. 16A shows experimental state tomography of the three-qubit Greenberger-Horne-Zeilinger (GHZ) state measured on a 3P quantum dot.

FIG. 16B shows the circuit diagram used to generate the GHZ state between the three nuclear spin qubits.

FIG. 16C is a schematic diagram of a quantum device including donor-bound electron spins experiencing local hyperfine fields.

FIG. 17 shows an example connectivity of electron and nuclear spin qubits in 2P and 3P dots, where each dot is operated as a logical qubit.

FIG. 18A shows an existing algorithm for correction of a single-qubit phase error in a system with three qubits.

FIG. 18B shows the implementation of the error correction algorithm in a 2P quantum dot according to aspects of the present disclosure.

FIG. 19 illustrates the shuttling mode for a 1D chain of four quantum dots and one electron.

FIG. 20 shows the connectivity of spin qubits for exchange coupled 2P and 3P dots.

FIG. 21A shows an example multi-donor dot array with four quantum dots.

FIG. 21B illustrates the connectivity available in the example array of FIG. 21A. This demonstrates a natural means to scale up as these multi-donor quantum dots arrays to form natural multi-qubit gates.

### DETAILED DESCRIPTION

Although the quantum processors and quantum dots described herein refer to donor atoms and unpaired electrons, it will be appreciated that these are merely examples and that the quantum processors and quantum dots of the present disclosure can be formed of donor or acceptor atoms (commonly referred to as dopant atoms) and unpaired electrons or holes can be confined in such quantum dots without departing from the scope of the present disclosure.

To date, a number of quantum processing architectures in silicon have been disclosed. One such architecture proposed in 1998 by B. E. Kane, included an array of nuclear spins located on donor atoms in silicon. Logical operations could be performed on such devices using electron-mediated nuclear spin interactions. Further, the electron-mediated nuclear spin interactions were controlled by voltages applied to metallic gates in the semiconductor device, enabling external manipulation of nuclear spin dynamics necessary for quantum computation.

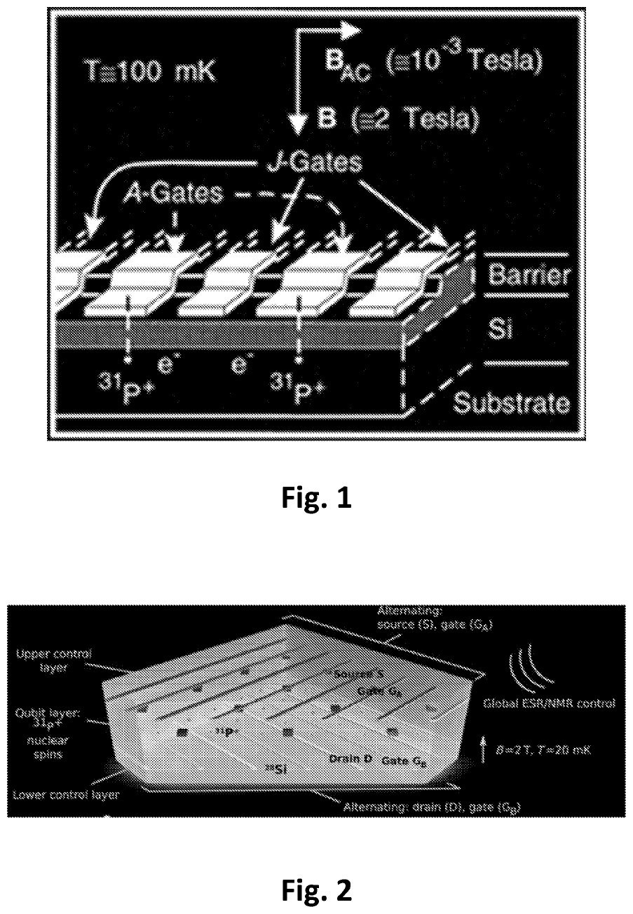

FIG. 1 illustrates two qubits in a one-dimensional array design based on the above architecture. The array includes phosphorous donor atoms and electrons in a silicon host. The donor atoms are positioned beneath the silicon substrate surface and gates are positioned above the silicon substrate surface. A gates control the resonance frequency of the nuclear spin qubits and J gates control the electron-mediated coupling between adjacent nuclear spins.

A quantum mechanical calculation using this architecture proceeds by the precise control of three external parameters: (1) A gates above the donors control the strength of the hyperfine interactions and hence the resonance frequency of the nuclear spins beneath them; (2) J gates between the donors turn on and off electron-mediated coupling between the nuclear spins; and (3) a globally applied AC magnetic field (BAC) flips nuclear spins at resonance. Custom adjustment of the coupling of each spin to its neighbours and to BAC enables different operations to be performed on each of the spins simultaneously. Finally, measurements are performed by transferring nuclear spin polarization to the electrons and determining the electron spin state by its effect on the orbital wavefunction of the electrons, which can be probed using capacitance measurements between adjacent gates.

Although this architecture can result in fast one-qubit and two-qubit logical operations using the A and J gates, it results in a number of challenges. For example, this architecture requires deterministic fabrication of single phosphorous donor atoms at precise locations and orientations in silicon. Further, there is limited tuneability of the exchange coupling (J) between qubits.

According to another quantum processor architecture in silicon, quantum information may be encoded on phosphorous donor atoms, which are arranged in a 2D square array. FIG. 2 shows this architecture that includes three planes. In the upper and lower planes, nanowires form a regular crisscross grid of control lines. In the middle plane, a 2D lattice of P donor qubits is patterned with atomic precision, tunnel-coupled to phosphorus-doped quantum dots that form islands of vertical single-electron transistor (SET) structures. The upper series of nanowires alternate as SET source(S) and upper gates (GA), whereas the lower complementary control line series alternate as SET drain (D) and lower gates (GB). Each qubit in this architecture is addressed by a set of upper/lower gate crossings around each cell. In any given unit cell, the SET island facilitates electron spin loading and unloading, controlled by bias conditions defined by the associated intersections of proximal source, drain, and gates. The bias conditions can be set to independently couple the SET island to a specific neighbour donor to load/unload an electron for activation/deactivation, and the control layout allows for multiplexing this operation across the array. Once qubits are activated, they can be controlled by externally applied (global) radio frequency (RF) and/or microwave (MW) fields acting on the nuclear-electron states to simultaneously perform single- and two-qubit quantum gates on the activated donor qubits, based on well-understood electron spin resonance (ESR) and nuclear magnetic resonance (NMR) techniques. Non-activated qubits are sufficiently detuned and remain unaffected by global control. Initialization and readout of the qubit nuclear spins follow well-established protocols based on swapping the quantum information from the nuclear spin to the electron spin, together with spin-dependent electron tunnelling to the SET island.

Although this architecture does not require vertical gates, it results in a number of challenges. Since this architecture is based on single donor atoms as qubits, it also requires deterministic fabrication of single phosphorous donor atoms at precise locations and orientations in Silicon. Further, gate operations between two qubits in this architecture can be slow.

In certain examples, electric dipole spin resonance (EDSR) may be utilized to control spin qubits with local electric fields. EDSR is generally achieved by coupling the spin of a qubit to the charge degree-of-freedom. This spin-charge coupling can be induced by a spin-orbit interaction. This so-called spin-orbit coupling (SOC) is generally present in atoms and solids-due to a relativistic effect, electrons moving in an electric-field gradient experience in their reference frame an effective magnetic field. In the case of silicon, however. SOC is intrinsically weak.

To increase the strength of SOC, several different mechanisms can be used such as the use of large spin-orbit coupling materials or large gradient magnetic fields from micro-magnets. Alternatively, the hyperfine interaction between electrons and surrounding nuclear spin qubits can be modulated to electrically control qubits without needing any additional control elements such as magnetic field generators, etc., and less power is needed to control the operation of the qubits.

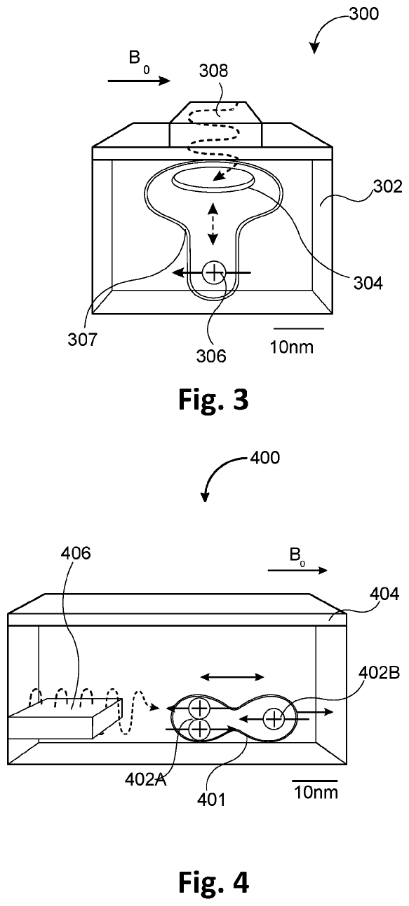

One such qubit processor architecture that utilizes hyperfine interaction between electrons and surrounding nuclear spins is one that incorporates flopping mode qubits that are based on a single electron spin that can be in two different charge states. By carefully tuning of the electric field (E), an electron can be put into a charge superposition between two sites (forming a charge qubit). If the electron spin Zeeman splitting is comparable to the charge qubit splitting, then the spin and charge states of the electron become hybridized. The hybridization results in a spin-charge coupling proportional to the difference in transverse terms of the Hamiltonian on each site. FIG. 3 illustrates one such flopping mode qubit called a flip-flop qubit.

In this arrangement, a qubit includes one quantum dot 304 and a donor atom 306. In the flip-flop qubit, the spin charge coupling arises from the hyperfine interaction of the electron spin with a nuclear spin of the single phosphorus donor atom 306, which can be used to generate electron-nuclear spin flip-flop transitions. The flopping-mode operation EDSR is performed by positioning the electron in a superposition of charge states between the donor nucleus and an interface quantum dot 304 created using electrostatic gate 308. In this charge superposition state, the hyperfine interaction changes significantly for small changes in detuning between the two sites.

In particular, FIG. 3 shows a quantum processing device 300 including a flopping mode qubit 307. The qubit 307 is formed of one quantum dot 304 and one donor atom 306 sharing a single electron and wave function. The donor atom 306 is located within the silicon substrate and the quantum dot 304 is formed near the interface to confine the electron of the donor atom 306. A gate 308 is positioned above the quantum dot 304 (on the dielectric).

The gate electrode 308 is operable to interact with the donor atom 306. For example, the gate 308 may be used to induce an AC electric field in the region between the interface and the donor atom 306 to modulate a hyperfine interaction between the electron located at the quantum dot 304 and the donor nuclear spin.

When electrically driving the qubit, the electron spin flip-flops with the nuclear spin of the donor. That is, the electric field can be used to control the quantum state of the qubit associated with the pair of electron-nuclear spin eigenstates i.e., ‘electron spin-up, nuclear spin-down’ and ‘electron spin-down, nuclear spin-up’.

These types of flopping-mode qubits have some disadvantages. For instance, this quantum processing device requires precise design and fabrication of the qubits-which is often very difficult to achieve.

Another type of flopping mode qubit architecture is shown in FIG. 4. The flopping mode qubit 401 in FIG. 4 includes two quantum dots 402A and 404B. Each quantum dot consists of a donor cluster. The qubit 401 uses a hyperfine interaction from the electron-nuclear system naturally present in donor systems to generate a synthetic spin-orbit coupling (SOC).

The whole device 400 is epitaxial—i.e., the donor clusters 402A, 402B are fabricated within the substrate and far from the interface. Each qubit may be controlled by one or more gates (one gate 406 shown here), which allow full electrostatic control of the qubit 401. DC electric fields, fast electric pulses and microwave (MW) electric fields can be applied on those two gates, either separately or jointly. One of the gates 406 can be tunnel coupled to one of the quantum dots (402A, 402B) in the pair, to allow loading and unloading of electrons onto the qubit 401. Due to the increased electrostatic coupling of that gate 406 to the qubit 401, it is advantageous to use that gate 406 to drive the qubit.

Qubit readout can be performed with a separate charge sensor (not shown) or dispersively using one of the one or more gates (e.g., gate 406) mentioned previously.

In the flopping mode, the qubit's electron-nuclear hyperfine interaction facilitates an effective energy gradient oriented along a transverse direction with respect to the external magnetic field—the magnetic field along this direction is used to drive the qubit. However, even this architecture has some issues—for example, logic operations have not be demonstrated in this architecture and each spin needs to be individually controlled.

Yet another quantum processing architecture utilizes singlet-triplet qubits. Two-electron singlet-triplet spin qubits offer the advantage of all-electrical control (that is, no need for a micro-magnet or a high-frequency RF antenna). Further, these qubits exhibit immunity to global magnetic field noise when compared to their single-spin qubit counterparts. The double quantum dots of this architecture can be disposed on a silicon substrate. In particular, the two quantum dots, each with one or more donors, are constructed side-by-side and tuned so that they are tunnel coupled. Singlet-triplet qubits can then be encoded in the double quantum dot sites. The smaller scale of the encoded singlet-triplet qubits enables large inter-qubit couplings in the order of 5 GHz-50 GHz; a regime not considered in previous quantum processor architectures. This larger coupling opens a pathway to realise faster two-qubit gates in a fault-tolerant quantum computing architecture, which are performed via an electric-dipole coupling (also termed ‘capacitive coupling’) between adjacent qubits.

However, this architecture also faces certain challenges. For example, logic operations have not been demonstrated in this architecture and each spin needs to be individually controlled.

Aspects of the present disclosure are directed to a novel quantum processing architecture and quantum processor that includes quantum dots formed of multiple donor atoms. Unlike previously known architectures, in which qubits are formed of either an electron spin or a nuclear spin, in the presently disclosed quantum processor the electron spins and/or nuclear spins of the quantum dots can be used to serve as qubits for various different types of quantum operations. For example, the electron spin may be used as a data qubit, while the nuclear spins of the quantum dot are used as atomic magnets. Similarly, the electron spin may be used as a data qubit while the nuclear spins of the quantum dot are used for error correction such that the dot can function as an error corrected logical qubit. In another example, the nuclear spins in a quantum dot can be used as data qubits, whereas the electron spin in the quantum dot is used to address or measure the nuclear spin qubits. In another example, the nuclear spins can be used as data qubits, whereas the electron spin in the quantum dot is used to couple the quantum dot to adjacent quantum dots via electron shuttling or exchange coupling. Finally, both the electron spin and one or more nuclear spins can be used in combination as data qubits.

This architecture and/or device is particularly beneficial in the near term in a so-called Noisy Intermediate-Scale Quantum (NISQ) era, where multi-donor quantum dots offer a number of benefits. However, this architecture will also allow the creation of large-scale universal quantum computer using STM fabricated atom qubits.

Typically, to perform a given algorithm, multiple quantum operations may be required such as initialization, a number of SWAP gates, a number of CROT gates, error correction, etc. Conventionally, multiple resources are needed to perform these operations and to date, known quantum architectures typically require a large number of control sequences to execute some or all of these quantum operations. The presently disclosed quantum processing architecture and device enables these multiple types of quantum operations to be performed relatively easily within the same quantum dot by using the quantum dot in the different modes described above. In particular, as described previously, the presently disclosed quantum processing system can encode quantum information in electron spins and/or nuclear spins of the quantum dots, thereby allowing either the electron spin or any one of the nuclear spins to be used for gate operations, to perform error correction, as data qubits, etc.

Further, as a quantum dot can include multiple donor atoms, the presently disclosed quantum processors are easier to fabricate than previously known systems. In addition, each quantum dot need not necessarily have the same number of donor atoms. Some quantum dots can have two donor atoms, others can have three donor atoms, and still others can have four or more donor atoms. The system is also tolerant in case some quantum dots are inadvertently fabricated with a single donor atom.

The presently disclosed quantum processing architecture can also be easily scaled in one, two, or three dimensions, where connectivity between adjacent dots can be achieved via electron shuttling or exchange coupling.

Further still, the multi-donor dot structures offer unique properties as they allow for multi-qubit gates within a native gate set, as well as single-qubit gates that can be constructed using these multi-qubit gates. Qubits can be encoded in the nuclear spins and/or electrons spins. Each multi-donor dot can be understood as a register of nuclear spin qubits coupled via hyperfine interaction to a single unpaired electron spin. Additionally, multi-qubit gates can be extended to a larger number of qubits using exchange coupling. Native multi-qubit gates provide an intrinsic advantage, as constructing such multi-qubit gates using one- and two-qubit gates is resource intensive. A reduced number of gate operations allows for a reduced circuit depth as more complex quantum algorithms can be executed within the qubit coherence times.

In addition to the above, the exchange interaction between quantum dots is more tunable between two adjacent asymmetric donor dots as opposed to adjacent symmetric single donor quantum dots, and as the exact spatial location of nuclear spins in the quantum dots may vary the resonant energy of each electron spin may be different from dot to dot, which improves the addressability of the quantum dots. That is, it is easy to tune and address individual quantum dots using global electrical or magnetic signals. Finally, the strong confinement potential created by the multi-donor quantum dots results in smaller electron wave functions and consequently longer relaxation or coherence times.

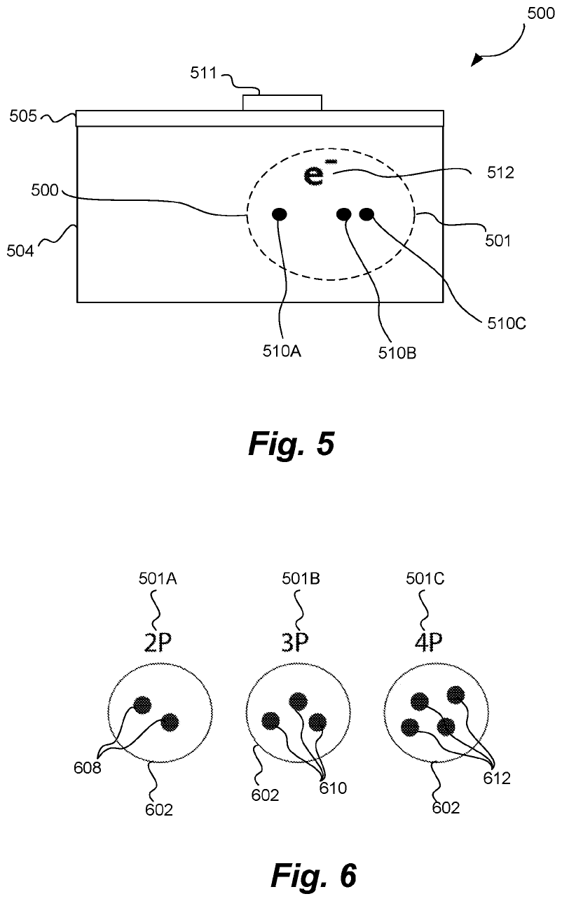

FIG. 5 illustrates an example multi-donor quantum dot device 500 as disclosed herein. The quantum dot device 500 includes a quantum dot 501 located in a semiconductor substrate 504. In this example, the semiconductor substrate 504 is 28Silicon. The silicon substrate 504 is topped by a barrier material/dielectric 505 such as silicon dioxide.

The multi-donor quantum dot 501 includes a plurality of dopant dots 510 embedded in the semiconductor substrate 504. In this example, the quantum dot 501 includes three dopant atoms, 510A, 510B, and 510C. The distance between the dopant dots is below the Bohr radius, such that the electron wavefunction covers all dopant atoms simultaneously. In one example, the distance is less than or equal to 3 nanometers.

Further, a gate 511 may be located on the dielectric 505 in a region above the donor cluster of donor atoms 510A, 510B and 510C. Voltages may be applied to gate 511 to confine one or more electrons 512 in the quantum dot 501. These electrons 512 are confined by the Coulombic potential of the donor atoms. In this example, one electron 512 is confined in the quantum dot 501. However, the 3P quantum dot shown in FIG. 5, can confine more electrons. It will be appreciated that although the gate 511 is shown as a surface gate, it can be (in some implementations) an in-plane gate that is fabricated within the silicon substrate in the same plane as the quantum dot 501.

Generally speaking, the donor atoms 510 are placed in the silicon substrate 504 with atomic-scale precision using scanning tunnelling lithography techniques. In particular, during fabrication, a lithographic patch can be defined in the semiconductor substrate. A predetermined number of donor atoms 510 can then be placed in the lithographic patch. In some examples, the donor atoms 510 may be located approximately 50 nm below the surface. In the example shown in FIG. 5, three donor atoms are placed in the lithographic patch.

As described above, the multi-donor quantum dot 501 may have two or more donor atoms. FIG. 6 shows a schematic of three different multi-donor quantum dots 501A-501C. The large circles 602 represent the wavefunction of an unpaired electron 512 confined to each multi-donor quantum dot 501. The small circles represent the donor atoms 608-612. For example, in multi-donor quantum dot 501A, there are two donor atoms 608 and an unpaired electron confined to the quantum dot 501A where the electron wavefunction is represented by 602.

In some examples, the donor atoms may be phosphorus atoms and a multi-donor dot with m phosphorus atoms may be denoted as an mP quantum dot—where m is an integer and m≥1. Therefore, the multi-donor quantum dots 501A-C may be denoted as 2P, 3P, and 4P quantum dots, respectively.

A quantum processor may be formed of a plurality of such multi-donor quantum dots 501 arranged in some sort of array or pattern. In addition to multi-donor quantum dots, such quantum processors may also include some single donor atom quantum dots (which may be similar to quantum dots described above with respect to FIG. 3).

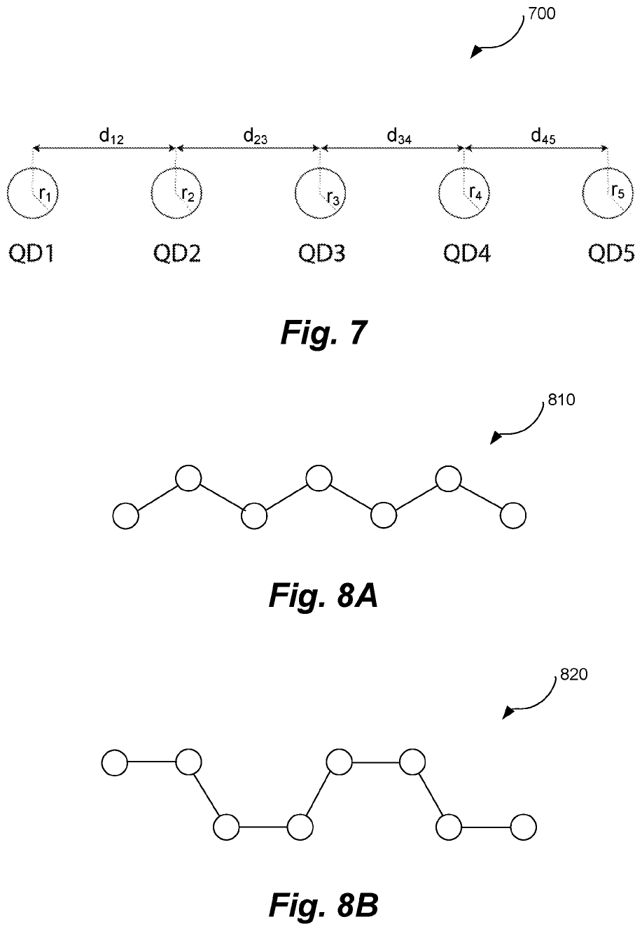

The quantum dot architecture may include a one-dimensional (1D) array of quantum dots. FIG. 7 shows an example architecture 700 including a 1D array of five quantum dots QD1-QD5. Each quantum dot may have one or more donor atoms. The inter-donor distance in any given quantum dot or the size of a quantum dot (r) is less than the Bohr radius. In some examples, this inter-donor distance/size of quantum dot is r≤3 nanometers. The inter-dot distance (d)—the distance between adjacent quantum dots may be in the range of 5-20 nanometers. It will be appreciated that the inter-dot distances (d) between quantum dots 501 may not be uniform, but may vary within the range 5-20 nanometers. Further, the size of a quantum dot (r) may be dictated by the number of donor atoms present in the quantum dot—the more number of donor atoms in a quantum dot, the larger its size or inter-donor distance r and the fewer the number of donor atoms in a quantum dot, the smaller its size. For example, the size of a 1P quantum dot may be about 0.7 nanometers, the size of a 2P quantum dot may be about 1 nanometer and the size of a 3P quantum dot may be about 1.5 nanometers.

FIGS. 8A and 8B each show an example of other quantum processor architectures 810, 820 that includes a 1D array of quantum dots with varying inter-dot distances and angles. The quantum dots are shown as circles positioned along the 1D array. For example, array 810 has a staggered geometry, where the quantum dots are not aligned along a single axis. Instead, odd-numbered quantum dots are positioned along a first line axis and even-numbered multi-donor quantum dots are positioned along a second line axis, where the first axis is parallel to the second axis.

The array 820 is similar to array 800, but in this case, pairs of quantum dots are positioned along the first and second line axes.

In yet other examples, a quantum processor that includes the multi-donor quantum dots described with respect to FIG. 5 may be formed of two-dimensional (2D) or three-dimensional (3D) patterns.

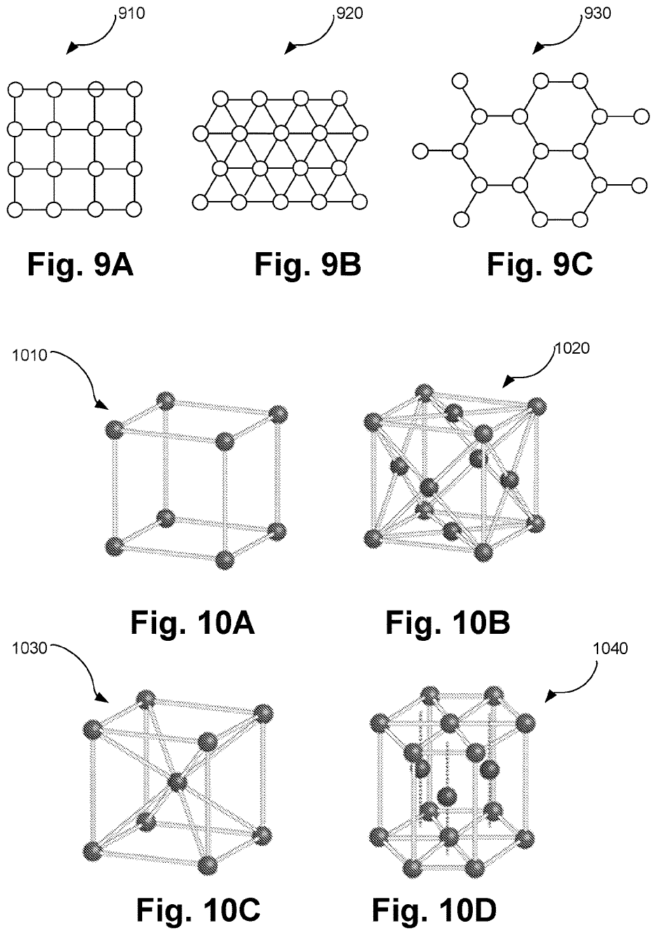

FIGS. 9A-9C shows three example 2D quantum processor architectures including multiple quantum dots 501 shown as circles. FIG. 9A shows an example 4×4 square lattice 910 including 16 quantum dots positioned at each of the intersections of the square lattice.

FIG. 9B shows an example triangular lattice 920 including 18 quantum dots positioned at each of the intersections of the triangular lattice. FIG. 9C shows an example hexagonal 2D lattice 930, where a quantum dot is positioned on each edge of the hexagonal lattice. Each quantum dot 501 in architectures 910-930 may have variable numbers of donor atoms, where the inter-donor distance is r₁≤3 nm. Further, the inter-dot distance between any two adjacent quantum dots may be in the range of 5-20 nm.

FIGS. 10A-10D depict example 3D quantum processor architectures including multiple quantum dots. In particular, FIG. 10A shows a cubic crystal structure 1010 showing 8 quantum dots, each quantum dot is positioned at a vertex of the cubic structure 1010. In this case, the distances between the quantum dots may be substantially uniform. In some examples, the crystal may be a simple orthorhombic crystal structure, where the nearest neighbour distances may vary along each of the axes dₓ≠d_{y}≠d_{z}.

FIG. 10B shows a cubic face-centred structure 1020 including 16 dots. In this example, a quantum dot is positioned at each vertex of the cubic structure and then a quantum dot is positioned in the centre of each face of the cube. FIG. 10C shows a cubic body-centred structure 1030 including 9 quantum dots. In this example, a quantum dot is positioned at each vertex of the cubic structure and then one quantum dot is positioned in the centre of the cube. FIG. 10D shows a hexagonal face-centred structure 1040 including 17 quantum dots. In this example, a quantum dot is positioned at each vertex of the hexagonal structure and then one quantum dot is positioned at each of the top and bottom faces of the hexagonal structure and three quantum dots are positioned in the middle of the hexagonal structure.

It will be appreciated that all the example architectures depicted in FIGS. 7-10 are merely exemplary. The quantum dots can be arranged in any of the depicted configurations or in any other 1D, 2D or 3D geometric arrangements without departing from the scope of the present disclosure as long as each quantum dot maintains the maximum size of less than the Bohr radius and the distances between adjacent quantum dots in any arrangement is between 5-20 nanometers.

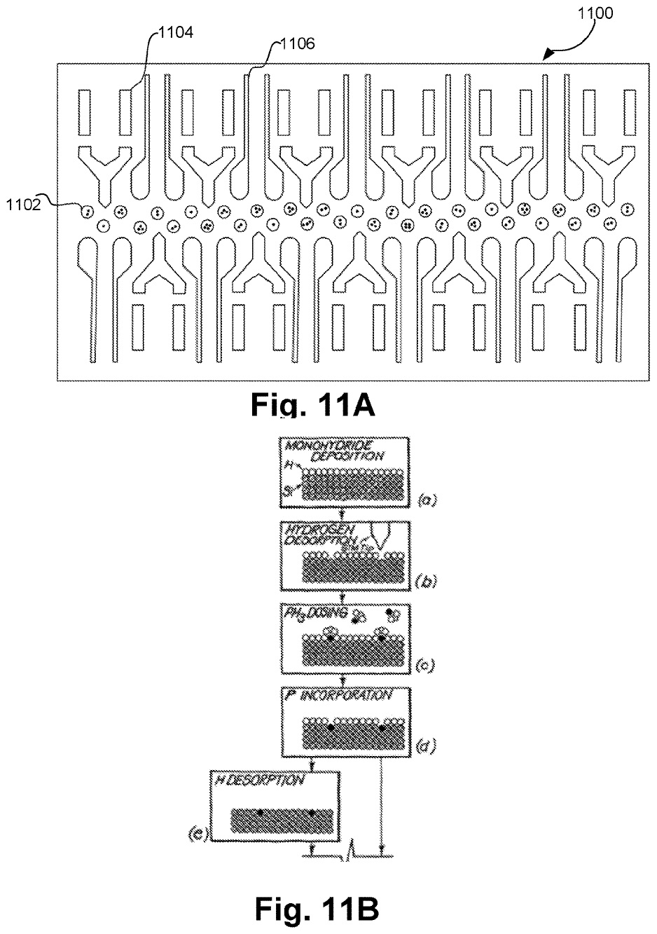

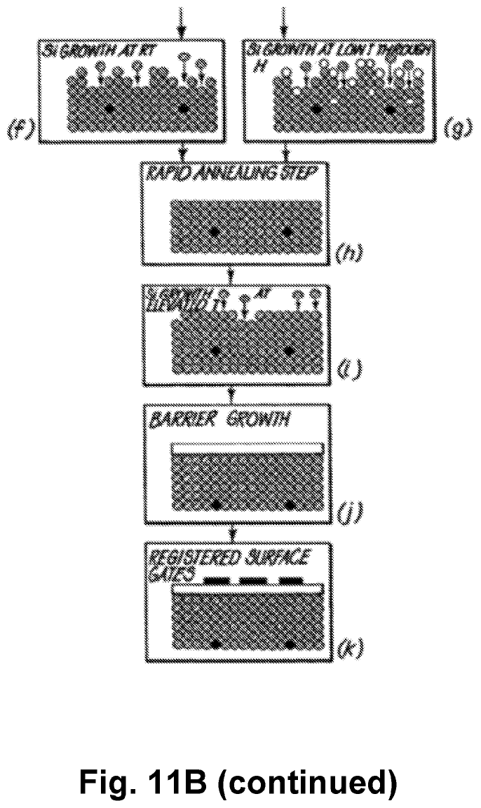

Further, it will be appreciated that FIGS. 7-10 only depict the arrangement of quantum dots in a quantum processor and do not depict any control gates, reservoirs, etc. FIG. 11A illustrates an example quantum processor 1100 including these additional elements. In particular. FIG. 11A depicts an array of quantum dots 1102 (including multi-donor quantum dot and zero or more single donor quantum dots). The processor 1100 further include a plurality of sensors 1104 and a plurality of control gates 1106. In this example, the quantum dot array is a 1D staggered array (similar to the 1D array 810) with 33 quantum dots.

It will be appreciated that the quantum dots in the array may contain different numbers of donors. In this example, there is a ratio of one sensor to three quantum dots. However, it will be appreciated that in other implementations or examples, the number of quantum dots per sensor may vary. Further still, in some examples, SETs may be used as sensors for reading out the qubits. In other examples, other types of sensors such as gates or single lead charge sensors may be used instead of the SETs for reading out the qubits. Electrons can be deterministically loaded and unloaded onto the dots 1102 by applying voltages to the gates 1106. In some examples, the sensors 1104 may also act as electron reservoirs for providing electrons to the quantum dots for confinement. In other examples, independent reservoirs may be provided, in addition to the charge sensors.

Although the quantum processor depicted in FIG. 11A shows the control gates and sensors in-plane with the quantum dots, this need not be the case in all implementations. In other cases, one or more of the control gates and/or one or more of the sensors may be formed about the surface of the semiconductor substrate whereas the quantum dots may be positioned within the semiconductor substrate. In still further examples, one or more of the control gates may be provided in the form of control lines above and below the quantum dots, e.g., as depicted in FIG. 2.

### Device Fabrication

FIG. 11B outlines the individual processing steps (steps a-k) for fabricating multi-donor quantum dots according to aspects of the present disclosure.

Initially, a clean Si 2×1 surface is formed in an ultra-high-vacuum (UHV) by heating to near the melting point. This surface has a 2×1 unit cell and consists of rows of σ-bonded Si dimers with the remaining dangling bond on each Si atom forming a weak π-bond with the other Si atom of the dimer of which it comprises.

Processing step (a) (i.e., monohydride deposition) involves exposing the clean Si 2×1 surface to atomic H to break the weak Si π-bonds, allowing H atoms to bond to the Si dangling bonds. Under controlled conditions a monolayer of H can be formed with one H atom bonded to each Si atom, satisfying the reactive dangling bonds, effectively passivating the surface; see step (a).

Next, at processing step (b) (i.e., hydrogen desorption), an STM tip is used to selectively desorb H atoms from the passivated surface by the application of appropriate voltages and tunnelling currents, forming a pattern in the H resist; see step (b).

It will be appreciated that H atoms are desorbed from precise locations where donor atoms are to be placed. For example, if the quantum processor includes a 2D square lattice of quantum dots, H atoms are desorbed in such a manner as to create multiple lithographic patches in a square lattice formation, where the distance between adjacent patches is between 5-20 nanometers. Further, the size of each of the lithographic patches created by the hydrogen desorption may depend on the number of donor atoms that are required to be placed in the quantum dots. In one example, if 1 donor atom is to be positioned in one of the lithographic patches (to form a 1P quantum dot) and two donor atoms are to be positioned in an adjacent lithographic patch (to form a 2P quantum dot), the STM tip may be utilized to desorb 6 hydrogen atoms in a first location to create a first patch and 15 hydrogen atoms may be desorbed in a second location 5-20 nanometers apart to create a second larger patch. Similarly, if larger number of donor atoms are to be placed in the patches, more hydrogen atoms can be desorbed to create lithographic patches of larger sizes. In other examples, the sizes of the patches may be smaller or larger than those described in the example above. Further still, in some examples, machine learning techniques may be utilized to control the number of donor atoms placed in any lithographic patch.

This process is repeated to create positions for other quantum dots. In this way regions of bare, reactive Si atoms are exposed along dimer rows, allowing the subsequent adsorption of reactive species directly to the Si surface.

Returning to FIG. 11B, at step (c) (i.e., PH3 dosing), phosphine (PH3) gas is introduced into the vacuum system via a controlled leak valve connected to a specially designed phosphine micro-dosing system. The phosphine molecule bonds strongly to the exposed Si surface, through the holes in the hydrogen resist; see step (c). As noted previously, at a particular donor site, a phosphine molecule may bond with any one of the exposed silicon dimers.

Subsequent heating of the STM patterned surface for crystal growth causes the dissociation of the phosphine molecules and results in the incorporation of P into the first layer of Si; see step (d). It is therefore the exposure of an STM patterned H passivated surface to PH3 that is used to produce the required donor molecules.

The hydrogen may then be desorbed, at step (e), before overgrowing the surface with silicon at room temperature, at step (f). An alternative is to grow the silicon directly through the hydrogen layer, as shown in step (g).

At step (h), the surface is rapidly annealed.

Silicon is then grown on the surface at elevated temperature, shown in step (i). In one example, approximately 50±10 nm of epitaxial silicon is grown at a temperature of 250° C. In some cases, a barrier, also known as a locking layer, may be grown as shown in step (j). Finally, conductive gates may be aligned on the surface, as shown in step (k) using electron beam lithography. Using registration markers, such as evaporated metal markers, the gates may be aligned at a lateral distance of 300±50 nm from the buried quantum dots. Further, an antenna may also be aligned on the surface to produce an oscillating magnetic field B1 perpendicular to the substrate at the position of the quantum dots.

The manner in which the quantum dots 500 are fabricated dictates how the donor nuclei and/or electrons within a quantum dot can be used as qubits. In particular, specific geometries and placement of donors within a lithographic patch or within a quantum dot enable reliable control of hyperfine coupling, tunnel coupling, and tunnel rate for controlling the quantum operations for a single-, two- or multi-qubit gates as described above.

Donor atoms incorporated within a given site form a collective confinement potential to bind electrons. The number of donors and their spatial configuration within each quantum dot determines the confinement strength. The confinement strength, in turn, determines the hyperfine couplings between the electron spin and each of the nuclear spins.

As described above, the lithographic openings can be patterned with approximately 5-20 nanometer separation such that the tunnel coupling between the electron spins bound to two neighboring dots allows for high-fidelity two-qubit gates between electron spin qubits.

In the presently disclosed quantum processors, quantum information is encoded within the electron spin and/or the nuclear spin. For electron spin, readout is achieved using a process called spin-to-charge conversion. In this process, a Single Electron Transistor (SET) charge sensor is used to determine the state of the electron spin qubit. The qubit-reservoir distance determines the electron tunnel rate—i.e. how quickly the electron spin can be measured. For fast and robust spin readout, the qubit-reservoir distance should ideally be around 10-25 nm.

### Control Methods

The electron spin and/or nuclear spin qubits in the multi-donor quantum dots 501 may be controlled using five main control methods: electron spin resonance (ESR), nuclear magnetic resonance (NMR), electrically driven spin resonance (EDSR), initialization, and readout.

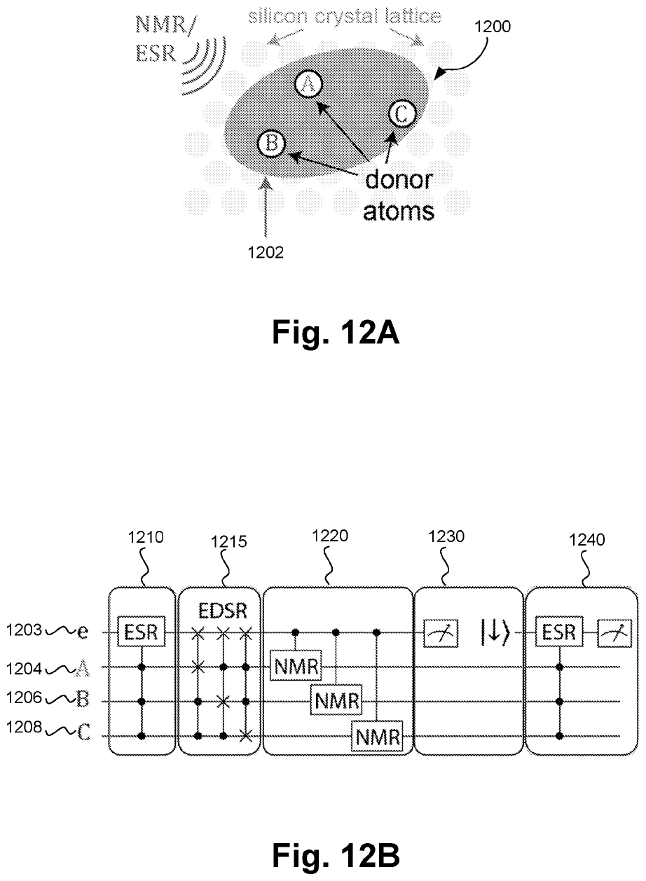

FIG. 12A shows an example 3P quantum dot 1200 with three donor atoms having nuclear spins denoted by A. B. and C. An electron is confined to this quantum dot 1200 and its wavefunction is represented by the ovoid 1202. FIG. 12B is a schematic of the control methods. The four vertical lines in the schematic represent the electron spin 1203 and the three donor spins 1204, 1206, 1208.

The first control method 1210 is ESR. This can be used to control the electron spin 1203. ESR is a direct means to drive an electron between its two spin states (up and down). In the presence of an external magnetic field B₀ an electron's spin energy levels are no longer degenerate. The two spin states |⬆ [symbol] , |⬇ [symbol] are separated by an energy difference ΔE. Thus, by applying an AC magnetic field to the quantum processor 1100, the electron spin 1203 can change from the spin-down state to the spin-up state, or vice-versa. ESR happens due to the coupling of the electron's magnetic moment to an external magnetic field.

In particular, ESR is a transition between opposite electron spin states but the same nuclear spin configuration. For example, in a 2P dot there are four ESR transitions: [symbol] ⬆ [symbol] |H_{ESR1}|⬇ [symbol] [symbol] , [symbol] ⬆ [symbol] |H_{ESR2}|⬇ [symbol] [symbol] , [symbol] ⬆ [symbol] |H_{ESR3}|⬆ [symbol] [symbol] , [symbol] ⬆ [symbol] |H_{ESR4}|⬇ [symbol] [symbol] . Where the first arrow indicates the spin state of the electron and the double arrows indicate the spin state of each of the two nuclear spins. For a 2P quantum dot there are four possible nuclear spin configurations: | [symbol] [symbol] , | [symbol] [symbol] , | [symbol] [symbol] , | [symbol] [symbol] .

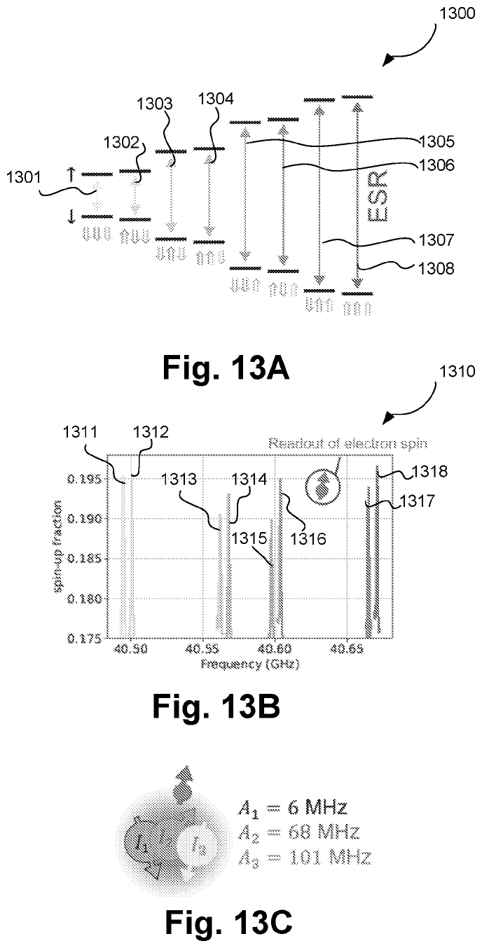

FIGS. 13A and 13B are plots that show the eight ESR transitions 1300 and frequencies 1310 of the 3P quantum dot 1200, respectively. For the 3P quantum dot 1200 there are a total of 23=8 nuclear spin configurations and a total of 16 total spin-states. The 8 nuclear spin states are shown by relative energy levels. The bottom row of states corresponds to the 8 nuclear spin states with the spin-down electron and the top row corresponds to the 8 nuclear spin states with the spin-up electron. There are also 8 vertical ESR transitions shown in FIG. 13A indicated by 1301-1308. The ESR transitions only flip the electron spin and leave the nuclear spins unaffected. Therefore, the ESR transitions connect the bottom states with the top state directly above it.

For example, in order to excite the 3P quantum dot 1200 from the spin state |⬇ [symbol] [symbol] to the spin state |⬆ [symbol] [symbol] , a single frequency corresponding to the ESR frequency shown in the plot 1310 may be applied to a control gate near the quantum dot. The ESR frequencies 1311-1318 correspond to the ESR transitions 1301-1308, respectively. The ESR frequency is proportional to the applied magnetic field and can be changed over a large range.

The second control method 1215 is EDSR. EDSR may be used to control the electron and nuclear spins in multi-donor dots. The EDSR transitions are electron-nuclear flip-flop transitions that can be performed via modulation of the hyperfine interaction between each nuclear spins 1204, 1206, 1208 and the electron spin 1203. This modulation of the hyperfine interaction may be achieved by applying an electric field that shifts the electron wavefunction away from the donor nucleus. As such. EDSR is mediated by an electric field that simultaneously flips the electron spin and one of the nuclear spins in the multi-donor system. For a 3P system, there are twelve possible EDSR transitions (not shown).

Another control method for use in controlling the nuclear spins in the multi-donor quantum dots is using nuclear magnetic resonance (NMR). This is shown as 1220 in FIG. 12B. In particular, NMR allows for control over the nuclear spins 1204, 1206, 1208, if the nuclear spins are individually addressable. Each nuclear spin in a multi-donor quantum dot may have a different hyperfine coupling strength. In one example 3P dot, the hyperfine coupling strength for the three phosphorus donors may be 6 MHz, 68 MHz and 101 MHz, respectively. In such a case, to flip the nuclear spin state from |⬇ [symbol] [symbol] to state |⬇ [symbol] [symbol] , an NMR pulse at the frequency corresponding to this transition may be applied using one or more of the control gates in the vicinity of the quantum dot 501.

As shown at 1220, three different NMR pulses are possible in this 3P system. Three additional NMR pulses are also available at different frequencies, corresponding to the electron being in the |⬆ [symbol] state rather than the |⬇ [symbol] state. The addressability frequencies of the individual nuclear spins depends on their environment. Typically, the frequencies to address nuclear spins is in the MHz range, while the EDSR and ESR frequencies to address electron spins are in the GHz range.

An electron spin initialization and measurement control is depicted at 1230 in FIG. 12B and a nuclear spin measurement control is depicted as 1240 in FIG. 12B.

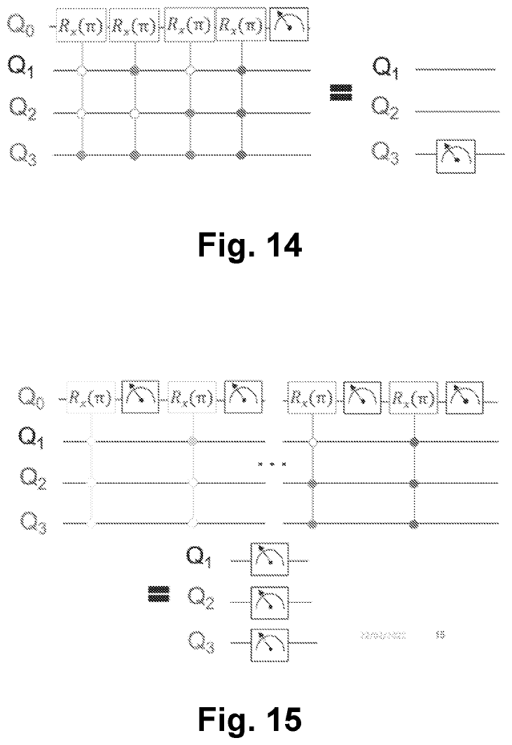

The initialization and measurement of the electron spin, depicted in 1230 in FIG. 12B, can be achieved using a spin-to-charge conversion process, for example Elzerman-style readout or ramped readout. The readout of nuclear spin can be achieved by combining ESR control with electron spin readout, as schematically shown in 1240 in FIG. 12B. The readout of nuclear spin relies on the fact that the ESR operation on the electron spin is conditional on the state of the nuclear spins within a given multi-donor dot. An example protocol for nuclear spin readout in a 3P dot is shown in FIG. 14. In this example, a series of four ESR pulses are applied to the electron spin 1203, where the four frequencies correspond to the nuclear spin marked as Q3 being in the up-state. Therefore, using a subsequent readout of the electron spin 1203, the state of the nuclear spin can be effectively determined. To read out all of the nuclear spins simultaneously, a protocol shown in FIG. 15 can be used, where ESR pulses at each frequency are applied and followed by a readout of an electron spin such that the exact combination of the three nuclear spin states can be determined.

### Modes of Operation

The above identified control mechanism may be employed on the example quantum processors described above to perform single-qubit, two-qubit and multi-qubit operations on the quantum dots. Where a multi-qubit operation is understood to be an operation on three or more qubits. To perform such quantum operations, the quantum dots can be operated in four different modes—a) using electron spins as data qubits and nuclear spins as atomic magnets, b) using electron spins as data qubits and nuclear spins for error correction, c) using nuclear spins as data qubits, and d) using both the electron spins and nuclear spins as qubits.

### Using Electron Spin as Data Qubits

In this mode of operation the nuclear spins are used as atomic magnets, whereas the electron spin is used as a data qubit. The nuclear spins increase or decrease the qubit energy. Nuclear spins of electron-hosting donor atoms affect the electron spin qubit energy splitting via the hyperfine interaction, A. The nuclear spins can be controlled using AC magnetic fields via nuclear magnetic resonance NMR or AC electric fields via EDSR. As such, the nuclear spins may be initialised into a predetermined spin configuration. In particular, controlling the orientation of the nuclear spins controllably creates energy difference ΔE_{z} between two electron spin qubits on adjacent quantum dots, affecting two-qubit gate operations between the two qubits.

The electron spin qubit encoding mode allows for efficient operation of an array of electron spin qubits whose splitting energies can be dynamically controlled. This is beneficial for addressability and high-fidelity two-qubit gates. When performing gate operations, adjacent electron spin qubits can be exchange coupled to perform the needed gate operations.

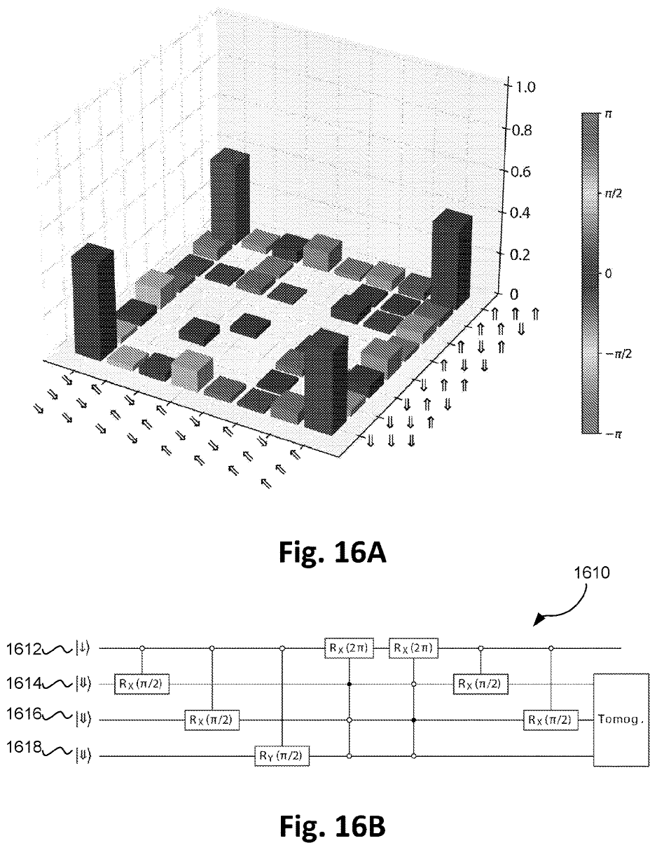

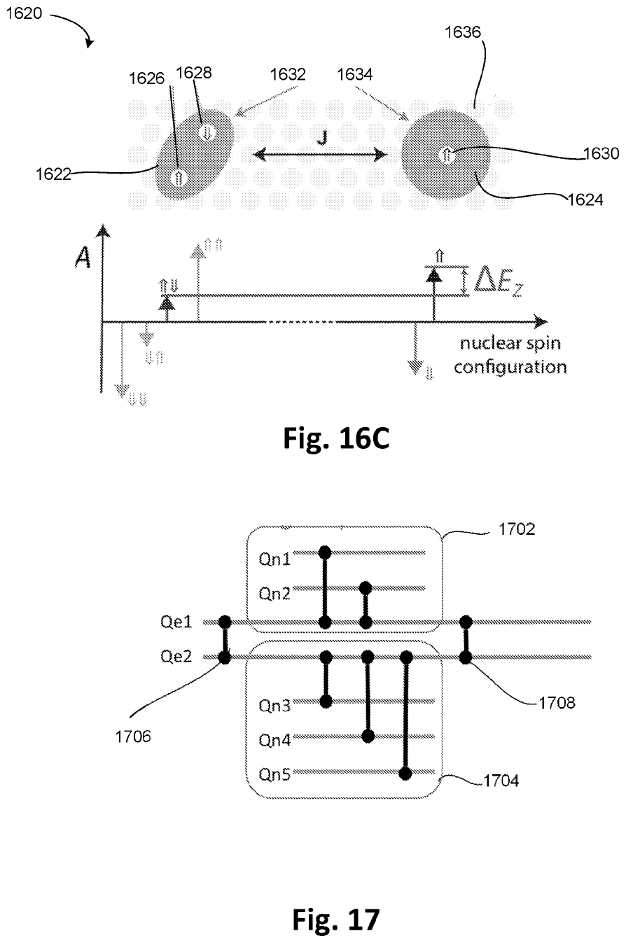

The operation of a four-qubit quantum processor consisting of three nuclear spins (3P) and one electron spin is demonstrated experimentally in FIGS. 16A and 16B.

FIG. 16A is a plot of the state tomography of a three-qubit Greenberger-Horne-Zeilinger (GHZ) state for the three nuclear spins. Where the GHZ state is an entangled quantum state involving at least three particles. The height and colour of each bar corresponds to amplitude and phase, respectively, of each element in the measured density matrix in the computational basis.

By comparing the measured state with the ideal three-qubit GHZ state, a fidelity of 79.7±2.0% can be determined. Where the ideal GHZ for three qubits is

$$\vert GHZ 〉 = ( \vert ⇑ ⇑ ⇑ 〉 + \vert ⇓ ⇓ ⇓ 〉 ) / √ 2$$

This confirms that the three nuclear spin qubits are entangled since the fidelity is greater than 50%. Successful creation of the GHZ state confirms the control methods described within this disclosure can be used in practice with high fidelities to operate multi-donor dots as multi-qubit processors.

FIG. 16B is a circuit 1650 used to generate the three-qubit GHZ state. The four vertical lines in the schematic represent the electron spin 1652 and the three donor spins 1654, 1656, 1658. At the start of the circuit 1650 the electron spin and the three nuclear spins are initialised in the spin-down state. The circuit consists of five NMR pulses and two ESR pulses. At the end of the circuit, a state tomography (Tomog. operation) is performed by measuring the x, y, and z projections of each nuclear spin independently to reconstruct the GHz density matrix.

FIG. 16C schematically illustrates two adjacent quantum dots 1622 and 1624 within a multi-qubit quantum processing device (such as device 1100). Each quantum dot may include one or more donor atoms. In this present example, the left quantum dot 1622 includes two P donor atoms 1626, 1628 and the right quantum dot 1624 includes one P donor atom 1630. Further, electron spin qubits can be confined by the P donors in the left and right quantum dots 1622, 1624, respectively. In particular, electrons can be spatially bound to the donor atoms in each quantum dot. In the example shown here, an electron may be confined by the pair of closely placed P donors in the left donor dot 1622, and another electron may be confined by the single phosphorus donor atom in the right donor dot 1624. The ovoids 1632 and 1634 around the dopant atoms illustrate the electron wavefunction. The shape of the ovoids and the electron confinement is determined based on the number of P atoms in each donor dot. As the left dopant dot includes two donor atoms, the electron wavefunction 1632 has an oval shape, whereas the right dopant dot includes one donor atom and the electron wavefunction 1634 is more spherical in shape.

For such quantum dots, the energy difference between the two quantum dots, ΔE_{Z}, is dominated by the hyperfine interaction, A, between electron (ovoids 1632 and 1634) and nuclear spins (double-lined arrows 1626, 1628 and 1630) and the orientation of the nuclear spins. The hyperfine interaction A can be controlled by a number of parameters, in particular the number of donor atoms in each of the quantum dots, arrangement of the donor atoms within the quantum dot and within the silicon crystal lattice 1636, number of electrons in the quantum dot, and strain and electric fields (applied/background fields) in the device.

### Error Correction

Quantum error correction (QEC) is an integral component for building a universal quantum computer. One type of error correction is a parity check operation, where single qubit bit-flip or phase-flip errors can be detected and corrected without measuring the encoded quantum state. A single multi-donor dot can be used as an error-corrected logical qubit using the electron spin as a data qubit while using nuclear spins for stabilizer measurements and error-correction schemes.

FIG. 17 shows example connectivity between nuclear and electron spin qubits that allows for error correction method to be applied to the 2P and 3P quantum dots. The top 3 lines in FIG. 17 correspond to the spins of the 2P dot (2 nuclear spins and 1 electron spin) and the bottom four lines correspond to the available spins in the 3P dot (1 electron spin and 3 nuclear spins). As shown in this figure, the electron spins of the two quantum dots can be used as data qubits and are exchange coupled with each other to perform two-gate operations (e.g., 1706 and 1708) whereas the nuclear spins of each of the quantum dots can be used as ancillary error correction qubits. In one example, the 2P quantum dot (2 nuclear spins and 1 electron spin) is used as a first logical qubit 1702 and the 3P quantum dot (3 nuclear spins and 1 electron) is used as a second logical qubit 1704.

The parity check operation is usually performed before and after other quantum operations. In some algorithms, this parity check operation may be performed at regular intervals in the algorithm.

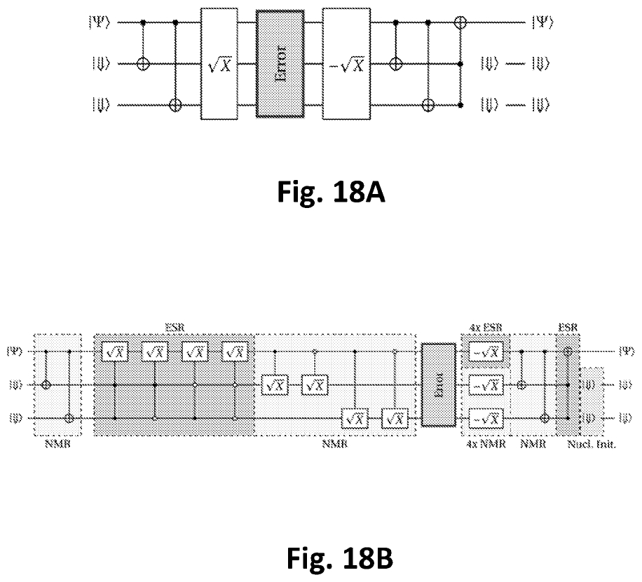

FIG. 18A shows an existing algorithm for quantum error correction (QEC) of a single-qubit phase error in a system with three qubits-one data qubit and two ancillary qubits. Each horizontal line in FIG. 18A represents a qubit namely, |Ψ [symbol] , | [symbol] ₁ [symbol] , | [symbol] ₂ [symbol] . The algorithm includes three stages: encoding, decoding and restoring. The encoding stage includes two CNOT gates and a rotation gate. The CNOT gate is performed on the first pair of qubits |Ψ [symbol] , | [symbol] ₁ [symbol] and then on the second pair of qubits |Ψ [symbol] , | [symbol] ₂ [symbol] . Next, a √X gate is applied to all three qubits. This gate performs a rotation over the X axis on all three qubits such that the error correction scheme corrects for the phase errors.

The next stage of QEC is the decoding stage. This stage comprises the opposite rotation gate −√X and the same CNOT gates in reverse. If an error has occurred in the first qubit |Ψ [symbol] , it is detected via the other two qubits | [symbol] ₁ [symbol] , | [symbol] ₂ [symbol] . This is done by flipping them conditionally on the state of |Ψ [symbol] via the CNOT gates.

The final stage of QEC is the restoring stage. This stage comprises one step where the state of |Ψ [symbol] is flipped conditionally on the other two qubits, correcting it if an error has occurred.

FIG. 18B shows the implementation of the same QEC in a 2P quantum dot according to aspects of the present disclosure. In a 2P dot, there is an unpaired electron and two nuclear spins-thus there is a total of three potential qubits or spins. The electron spin is the data qubit and labelled as |Ψ [symbol] and the two nuclear spins act as ancillary qubits and are labelled as | [symbol] ₁ [symbol] , | [symbol] ₂ [symbol] where the subscript differentiates the two nuclear spins.

The sequence commences with the encoding stage comprising two CNOT gates and four √X rotation gates. The CNOT gates are performed between the electron spin and each of the nuclear spins using NMR. Then, four electron √X rotation gates are applied using ESR. For example, a √X gate may be performed to the electron |Ψ [symbol] based on the condition that: both of the nuclear spin in the dot are in the state |1 [symbol] ; one of the nuclear spins is in the state |1 [symbol] ; none of the nuclear spin in the dot are in the state |1 [symbol] . Here, all four possible ESR √X gates have been applied, together implementing a single qubit √X gate on the electron.

Next, four other √X rotation gates ae applied to the two nuclear spins based on the condition that the electron spin is in the |1 [symbol] state or the |0 [symbol] state. These phase gates are applied using NMR similarly to the ESR pulses described above, and apply single-qubit √X gates on both nuclear spins. Each pair of NMR gates (i.e., applied to each nuclear spin for different electron spin conditions) performs a single qubit gate on the respective nuclear spin. The reason for the repeat is that the pulse must be conditioned on all possibilities of the other spins in order to decouple them.

Next, the opposite gate is performed (−√X) using ESR and NMR as described above. CNOT gates are again applied after that using ESR and lastly the conditional flipping of the electron state is performed based on the state of the nuclear spins.

This way, if an error has occurred in either the electron spin or one of the nuclear spins, it can be detected via the 2P quantum register, and subsequently corrected. This entire sequence can be repeated through re-initialisation of the nuclear spins, extending the coherence time and hence quality of quantum operations performed with multi-donor quantum dots.

It will be appreciated that QEC may be performed in a similar manner on quantum dots with three or more donor atoms.

Using Nuclear Spins as Data Qubits while Using Electrons for Readout and Addressability

Nuclear spins can be used as data qubits for other operations-such as storing data. In these cases, nuclear spins can be readout via the electron spin in the quantum dot. When an electron is present at a multi-donor quantum dot, the individual nuclear spins can be addressed using a particular NMR or EDSR frequency as the hyperfine coupling provides addressability as described above. Further, the single-qubit gates on nuclear spins can be achieved by combining EDSR and ESR techniques, or directly using NMR. Further still, multi-qubit gates can be performed between nuclear spin qubits within the same dot via the hyperfine coupling geometric gates using ESR.

### Using Nuclear Spins as Data Qubits and Electron Spins for Coupling Adjacent Dots

In the shuttling mode, an electron can be shuttled between adjacent quantum dots. This may be useful to coherently transfer information from one quantum dot to another. It can also be used to change the addressability of the quantum dots. For example, if an electron resides on a dot, each of the nuclei can be controlled individually, whereas if the dot does not have an electron the nuclei can only be controlled all at once. This could be used to either perform global gates on many qubits, or decrease the spectral density required to control many qubits by “turning them off” by removing the electron. When used to transfer data, the nuclear spins may be used as data qubits as they have longer coherence times and the electron spins can be used to transfer the data from one quantum dot to another.

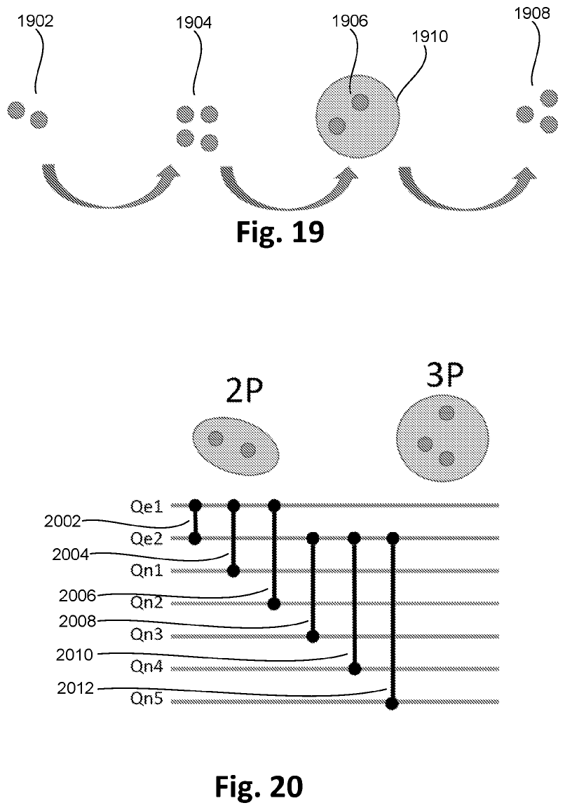

FIG. 19 illustrates the shuttling mode for a 1D chain of four quantum dots 1902, 1904, 1906, 1908 having 2P, 4P, 2P and 3P configurations, respectively. In this example, one electron is confined to the first 2P dot and no other electrons are confined to the other quantum dots.

The electron may be shuttled from the first dot to the second dot by tuning voltages of one or more control gates near these quantum dots. Then, the electron can be shuttled between the second and the third quantum dots by tuning gate voltages near the second and third quantum dots. Similarly, the electron can be shuttled between the third and fourth quantum dots by tuning gate voltages near the third and fourth quantum dots. In this example an electron wavefunction 1910 is shown on the third quantum dot after it was shuttled from the second quantum dot and before it is shuttled to the fourth quantum dot.

It will be appreciated that while this mode primarily operates on a single unpaired electron, it is possible to utilise this mode on multiple unpaired electrons simultaneously where the number of unpaired electrons is smaller than the number of quantum dots.

In this mode, the inter-dot coupling can be achieved by entangling a nuclear spin with electron via the hyperfine interaction, and subsequently moving the electron in a coherent way to a different dot. Effectively, the electron mediates an entangling gate between nuclear spins located in separate dots. An entangling gate is a gate that acts nontrivially on two or more qubits in the sense that the effect cannot be achieved using only single qubit gates. The states of each qubit in the entangled gate depends on the state of the other qubit in the gate. In one example, an entangling gate could be a two-qubit CNOT gate, a two-qubit \sqrt{SWAP} gate, a three-qubit Toffoli gate, etc. In the present mode, the entanglement can be distributed throughout the multi-donor dot quantum processor 1100 via exchange-based electron-electron gates or by shuttling electrons from one dot to another.

Importantly, the nuclear spins of all un-occupied donor dots share the same resonance frequency. This means that all idling qubits (i.e., quantum dots that do not have an electron spin) have the same resonance frequency and can be actively decoupled from the noisy environment via a series of NMR control pulses in a straightforward way.

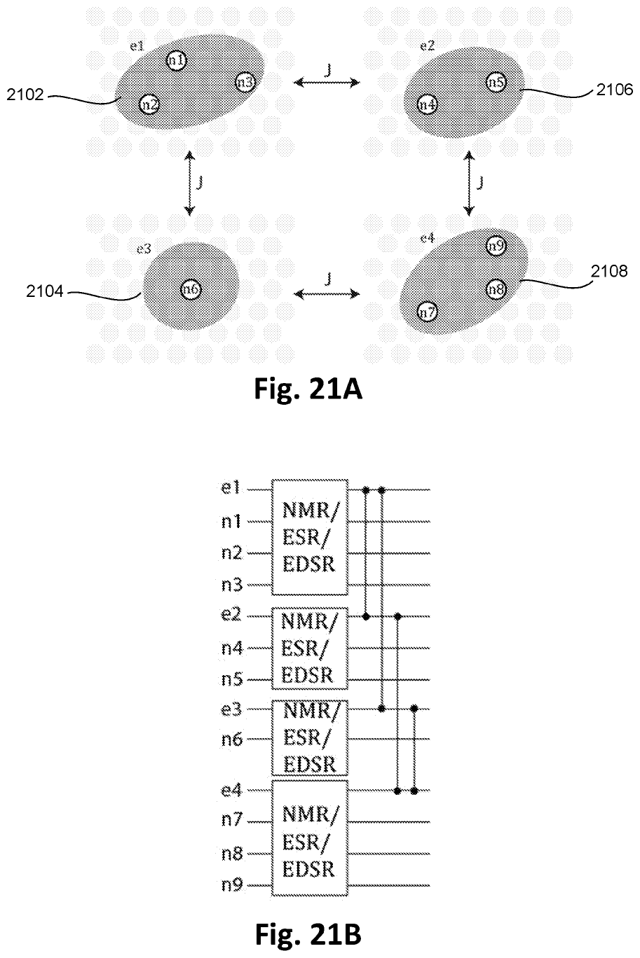

In the exchange coupling scheme, the connectivity between adjacent dots can be achieved using exchange coupling controlled via gate voltages. Specifically, in this mode, adjacent quantum dots will both have electron spins present and two qubit gates, such as CROT gates, conditional phase gates and \sqrt{SWAP} gates can be performed between them, as opposed to the qubit shuttling mode of operation discussed previously where there is only one electron between adjacent dots, which is transported back and forth. FIG. 21A shows four quantum dots 2102, 2104, 2106 and 2108 in a two dimensional array. In this example, adjacent quantum dots that is quantum dots 2102 and 2106, 2106 and 2108, 2104 and 2108 and 2102 and 2104 are exchange coupled (J) via their respective electron spins such that two-qubit operations can be performed between the adjacent quantum dots.

### Combination Mode

In this mode, the qubits can be encoded in either the electron or any one of the nuclear spins of a quantum dot. In this scheme, electron spin qubit is coupled to all nuclear spin qubits within a given quantum dot. Additionally, all spins at two neighbouring donor dots are coupled via controllable exchange interaction.

FIG. 20 shows coupled spins for a 2P and 3P dot that are coupled via the exchange interaction J. In this example, the electron from the 2P dot Qe1 and the electron from the 3P dot Qe2 are coupled—illustrated by the connection 2002. Electron Qe1 is also coupled to both nuclear spins in the 2P dot (2004, 2006). And electron Qe2 is coupled to all three nuclear spins in the 3P dot (2008, 2010, 2012).

In this operation mode, any of the six qubit interactions may be addressed using ESR, NMR, EDSR and by controlling the exchange coupling. This exchange interaction may be controlled by applying voltages to one or more control gates near the respective quantum dots. When switched on, the exchange interaction enables a multi-qubit gate between two electron spins and all nuclear spins linked to these two electrons.

FIG. 21A shows an example multi-donor dot array with four quantum dots 2102-2108. In this array, there are four electrons, one bound to each of the quantum dots. The electrons are labelled e1, e2, e3, e4. The donor dots in this system may be denoted as a 3P (2102), 1P (2104), 2P (2106) and 3P (2108) quantum dot. In this mode, each electron spin qubit is coupled to all nuclear spin qubits within a given donor dot. Additionally, all spins at two neighbouring donor dots are coupled via controllable exchange interaction.

FIG. 21B illustrates the connectivity available in this example array. This demonstrates a natural means to scale up as these multi-donor quantum dots arrays form natural multi-qubit gates.

The term “comprising” (and its grammatical variations) as used herein are used in the inclusive sense of “having” or “including” and not in the sense of “consisting only of”.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method for performing one or more quantum operations on a quantum processor, the quantum processor comprising a plurality of quantum dots in a semiconductor substrate, at least a subset of the quantum dots being multi-dopant quantum dots, each multi-dopant quantum dot comprising two or more dopant atoms, and at least one of the plurality of quantum dots confining an unpaired electron/hole, the method comprising:
performing the one or more quantum operations on the quantum processor using one or more operation modes including:
using the spin of the unpaired electron/hole of a quantum dot as a data qubit;
using a multi-dopant quantum dot as an error corrected logical qubit;
using at least one nuclear spin of a dopant atom of a multi-dopant quantum dot as a data qubit; or
using the spin of the unpaired electron/hole and at least one nuclear spin of a dopant atom of a multi-dopant quantum dot as data qubits.

2. The method of claim 1, wherein adjacent quantum dots in the plurality of quantum dots are positioned 5-20 nanometers apart.

3. The method of any one of claims 1-2, wherein when the spin of the unpaired electron/hole of a quantum dot is used as a data qubit, the nuclear spins of the one or more dopant atoms in the quantum dot are used as atomic magnets.

4. The method of any one of claims 1-2, wherein when the multi-donor quantum dot is used as the error corrected logical qubit, the spin of the unpaired electron/hole of the multi-donor quantum dot is used as a data qubit and the nuclear spins of the one or more dopant atoms of the multi-dopant quantum dot are used for error-correction.

5. The method of any one of claims 1-2, wherein when at least one nuclear spin of a dopant atom is used as a data qubit, and the spin of the corresponding unpaired electron/hole is used for readout, addressability, or coupling with adjacent quantum dots.

6. The method of claim 5, wherein coupling with adjacent quantum dots is performed via electron/hole spin shuttling between the multi-dopant quantum dot and an adjacent quantum dot or via exchange coupling between an unpaired electron/hole of the multi-dopant quantum dot and a paired electron/hole of the adjacent quantum dot.

7. The method of any one of the preceding claims, wherein the nuclear spins of the dopant atoms are controlled using nuclear magnetic resonance or EDSR.

8. The method of any one of the preceding claims, wherein the spin of the unpaired electron/hole is controlled using electrical spin resonance or EDSR.

9. The method of any one of the preceding claims, wherein the one or more quantum operations include at least one of single-qubit gate operations, two-qubit operations, or multi-qubit operations.

10. The method of claim 9, wherein when the one or more quantum operations is a multi-qubit operation, the quantum operation is performed using the spin of the unpaired electron/hole and the nuclear spins of the dopant atoms in a multi-dopant quantum dot.

11. A method for performing one or more quantum operations on a quantum processor, the quantum processor comprising a plurality of quantum dots in a silicon substrate, at least a subset of the quantum dots being multi-dopant quantum dots each comprising two or more dopant atoms, and at least one of the plurality of quantum dots confining an unpaired electron/hole, the method comprising:
performing the one or more quantum operations on the quantum processor using one or more modes of operation comprising at least one of:
using one or more of the multi-dopant quantum dots as error corrected logical qubits;
using at least one nuclear spin of a dopant atom of a multi-dopant quantum dot as a data qubit; or
using the spin of the unpaired electron/hole and at least one nuclear spin of a multi-dopant quantum dot as a data qubit.

12. A quantum processor comprising:
a silicon substrate,
a layer of dielectric material on the silicon substrate;
a plurality of quantum dots fabricated in the silicon substrate, each quantum dot comprising at least one dopant atom, at least a subset of the quantum dots being multi-dopant quantum dots having two or more dopant atoms, and one or more of the plurality of quantum dots confining an unpaired electron/hole;
wherein during operation of the quantum processor the spin of the unpaired electron/hole and/or the nuclear spin of the one or more dopant atoms in a quantum dot are used as data qubits.

13. The quantum processor of claim 12, wherein the number of dopant atoms and/or spatial configuration of the dopant atoms within each quantum dot is selected to achieve a predefined hyperfine coupling range between the spin of the unpaired electron/hole and each of the nuclear spins within each quantum dot.

14. The quantum processor of any one of claims 12-13, wherein the distance between two adjacent quantum dots is selected to achieve a predefined tunnel coupling range between the spins of the unpaired electrons/hole bound to the adjacent dots.

15. The quantum processor of any one of claims 12-14, wherein the distance between adjacent quantum dots is approximately 5-20 nanometers.

16. The quantum processor of claim 14, wherein the predefined tunnel coupling is in a range of 1 kHz-1 THz.

17. The quantum processor of any one of claims 12-16, wherein the size of each quantum dot is less than 3 nanometers.

18. The quantum processor of any one of claims 12-17 further comprising:
one or more sensors for measuring the final state of a qubit associated with a quantum dot of the plurality of quantum dots.

19. The quantum processor of any one of claims 12-18 further comprising:
one or more reservoirs in the vicinity of the quantum dots, the one or more reservoirs providing electrons/holes for confinement in one or more of the quantum dots;
wherein the distance between the one or more reservoirs and the one or more quantum dots is approximately between 10-25 nanometers.

20. The quantum processor of any of any one of claims 12-19 wherein the plurality of quantum dots are arranged in a one-dimensional, two-dimensional, or three-dimensional geometric pattern.

21. The quantum processor of any one of claims 12-20, wherein during operation:
when the spin of an unpaired electron/hole of a quantum dot is used as a data qubit, the nuclear spin of the one or more dopant atoms of the quantum dot are used for error correction or as atomic magnets;
when the nuclear spins of the one or more dopant atoms are used as data qubits, and the spin of the unpaired electron/hole is used for addressing or measuring the nuclear spins of the one or more dopant atoms; or
when the nuclear spins of the one or more dopant atoms are used as data qubits, and the spin of the unpaired electron/hole is used for coupling the quantum dot to an adjacent quantum dot.

22. A method for performing a multi-qubit operation, the method comprising:
providing a multi-dopant quantum dot comprising two or more dopant atoms and an unpaired electron/hole confined in the multi-dopant quantum dot;
using a spin of the unpaired electron/hole and the nuclear spins of the two or more dopant atoms as qubits and performing the multi-qubit operation using the qubits.
